(19) United States
(12) Patent Application Publication
(10) Pub. No.: US 2003/0000058 A1
(43) Pub. Date: Jan. 2, 2003

(54) Method for manufacturing a film bulk acoustic wave filter

(75) Inventors: Shu-Hui Tsai, Hsin-Chu City (TW); Chengkuo Lee, Hsin-Chu City (TW); Chung-Hsien Lin, Chia-I City (TW); Ju-Mei Lu, Ma-Kung City (TW)

Correspondence Address: BRUCE H. TROXELL, SUITE 1404, 5205 LEESBURG PIKE, FALLS CHURCH, VA, 22041, US

(73) Assignee: ASIA PACIFIC MICROSYSTEMS, INC.

(21) Appl. No.: 10/126,541

(22) Filed: Apr. 22, 2002

(30) Foreign Application Priority Data
Jun. 27, 2001 (TW) 090115536

(51) Int. Cl. H04R 17/00; H05K 3/02

(52) U.S. Cl. 29/25.35; 29/846; 29/831

(57) ABSTRACT

A method for manufacturing a film bulk acoustic wave filter, wherein a single-layer high-acoustic-impedance reflection layer is applied for the film bulk acoustic wave, for example, a diamond film with single-layer high-acoustic-impedance or a BCB film with single-layer low-acoustic-impedance is used as a reflection layer under the film bulk acoustic wave device in order to replace the cavity-reflective construction or the multi-layer reflection construction that are presently used; thus, there is no need for etching the cavity, the steadiness of the device and the yield of the device can be improved, and the FOM (figure of merit) of the film acoustic wave device is also improved; further, as there is no backside etching and front-side etching proceeded, the size of die is reduced greatly, so it is advantageous to mass production.

### FIELD OF THE INVENTION

The present invention relates to a method for manufacturing a film bulk acoustic wave filter, especially to a steady film bulk acoustic wave filter and the manufacturing method thereof, wherein the reflection layer under the bulk acoustic wave device is formed by single-layer high-acoustic-impedance reflection film, so that the manufacturing processes are simplified, the size of the die is reduced, and the efficiency of the device is improved.

### DESCRIPTION OF THE RELATED BACKGROUND

The mobile communication is so vigorously developed that speed up the requirement of the RF (radio frequency) wireless electronic device. The mobile ability of the wireless communication product is depended on the size of device and the lifetime of battery. Also the devices manufacturers are dedicated to develop the tiny, cheaper and the more well performance devices. The finally step to microminiaturize the device is to integrate it with IC to form a system on chip (SOC). Presently, in the HF front-end of the wireless system, one of the devices that still can not be integrated with the IC, is RF front-end filter. In the future, the RF front-end filter will be the occupied space and the necessary device in the double, triple or multiple-band standards. The multiplexer obtained by associating the RF switch with RF front-end filter would be the key to decide the communication quality.

The ordinarily used RF front-end filter is the surface acoustic filter. In the past, the surface acoustic filter is not only to be the RF front-end filter but also to be the channel selective filter in the IF (intermediate-frequency) band. But in accompany with the development of the direct conversion technique (that is, the zero-IF or near zero-IF technique), it does not need more analog IF filter, so the application of the surface acoustic filter can only be extended to the RF filter. But the surface acoustic filter itself has the larger insertion loss and it has worse power dissipation stand. In the past, the insertion loss standard in the use of IF band selective filter is not rigorous, and the IF band belongs to the RF back-end so that it is not necessary to use a well power dissipation stand. But now, if it is used in the RF front-end, the aforementioned both standards will be the problem to the surface acoustic filter.

In order to solve the problem, the Sumitomo Electric company in Japan disclosed the growing across finger electrode on the Zinc Oxide/Diamond/Silicon substrate. It used the high spring constant and well thermal conductivity of the Diamond, so the across finger electrode on the compound substrate could stand about 35 dBm dissipation and still could maintain the well linearity. But it is rather expensive about the Diamond substrate, and the line pitch of the across finger electrode is below micrometer, and it has the lower error tolerance and expensive in the equipment investment.

The other product of RF filter is the Low Temperature Cofired Ceramics (LTCC). The Low Temperature Cofired Ceramics (LTCC) owns the best benefit of higher stand to the RF dissipation. However, it still has other problems that have to be solved, such as: the difficulty in measurement, and not easy to get the ceramic powder from the upper company, and the ceramic happened the shrinkage phenomenon in the manufacturing processes that the deviations of products were caused and it is difficult to modify.

### DESCRIPTION OF THE PRIOR ART

Recently, the technique about the bulk acoustic wave filter device, such as the Film Bulk Acoustic Resonator (FBAR) device (refer to the U.S. Pat. No. 6,060,818) developed by HP company, and the Stack Bulk Acoustic Resonator (SBAR;) device (refer to the U.S. Pat. No. 5,872,493) provided by Nokia company, which could diminish the volume of the high efficiency filter product, and it could operate in 400 MHz to 10 GHz frequency band. The diplexer using in the CDMA mobile phone is one kind of said filter product. The size of the bulk acoustic wave filter is just a part to the ceramic diplexer, and it owns better rejection, insertion loss, and power management ability than the surface acoustic filter. The combination of those properties could make the manufacturer produce high performance, up-to-date, and mini-type wireless mobile communication equipment. The bulk acoustic wave filter is a semi-conductor technique, so it could integrate the filter into the RFIC, and to form the system on chip (SOC).

It is necessary to form a vacant construction below the resonator in the FBAR device. In general, a developed way is to fabricate the vacant construction by backside etching or front-side etching the substrate. As the backside etching is being proceeded, the density of the devices thereof is restricted greatly. As shown in FIG. 1, a supporting layer 14, a lower electrode pattern 12′, a piezoelectric material layer 13, and an upper electrode metal pattern 12 are formed sequentially. Thereafter, rear etching is proceeded to form a cavity 10 in the desired resonator region. It needs more time for backside etching since the etching depth of backside etching is relatively deep; and it also needs quite a long time for front-side etching since the side etching is performed from the side of non-crystalline to excavate the substrate below the resonator. As shown in FIG. 2, a supporting layer 24, a lower electrode pattern 22′, a piezoelectric material layer 23, and an upper electrode metal pattern 22 are formed sequentially onto the substrate 21. Thereafter, front-side etching is proceeded to form a cavity 20 on the desired resonator region, and the silicon substrate residue 28 is remained.

FIG. 3 is a cross-sectional view showing the bulk acoustic wave filter proceeded with front-side etching by using a sacrificial layer according to the U.S. Pat. No. 6,060,818 of the HP company. As shown in FIG. 3, the bulk acoustic wave filter device can be formed on a substrate 31. First, a cavity 30 is mask defined and etched on the substrate. Then a sacrificial layer 35 is deposited onto this region. Then the sacrificial layer 35 is performed with polishing process by using the methods of chemical-mechanical milling. Afterwards, the supporting layers 34, the lower electrode patterns 32′, the piezoelectical material layers 33, and the upper electrode metal patterns 32 are formed sequentially onto the construction. Then, front etching is being performed on the desired resonator region to remove the sacrifice layer 35, and a cavity 30 is formed, so that the device properties would not be influenced by the substrate. There are disadvantages that the sacrificial layer 35 should have a specified thickness in order to form a cavity deep enough for avoiding the influence of the substrate. And the smoothening process, such as being pre-grooved on the substrate and the chemical-mechanical milling process to the sacrifice layer, is necessary for proceeding the manufacturing process.

Besides, in general, there is a problem with the FBAR devices while front-side etching. That is, the upper electrode patterns 22, the lower electrode patterns 22′, the piezoelectric material layers 23 and the supporting layers 24 have to be etched in order to form etching windows 26, so that the etchant can pass through the etching windows 26 to form the cavity 20. However, it is difficult to form patterns onto the piezoelectric material layers. The conventional way is by metal mask, ion milling dry etching, or laser machining. Such methods have difficulties in cost and processes, and are very difficult to achieve large-area etching and etching uniformity.

In SBAR device, although the vacant construction is not necessary to be formed below the resonator, a multi-layer film is necessary to be grown. Such processes are rather complicated and not advantageous to integration. The selection of the materials for the Bragg reflection layer is restricted, so the device yield is relative low, but it still has an advantage of multiple selectivity of the substrate.

FIG. 4 shows a stack bulk acoustic resonator device developed by the Nokia Company (referring to the U.S. Pat. No. 5,872,493). As shown in the figure, the bulk acoustic resonator device can be formed on a substrate 41, and the buffer layer 42, the high-acoustic-impedance layers 43, 44, 45, 46 and the low-acoustic-impedance layers 43′, 44′, 45′, 46′ are formed sequentially and alternately, so that a stacked construction having a thickness of quarter wavelength is grown. Afterwards, the lower electrode metal layer 47, the piezoelectric layer 48, the upper electrode metal pattern layer 49 are formed sequentially onto this construction. Such method has an advantage according to the substrate properties. That is, since the acoustic wave is spreaded completely in the piezoelectric layer 48 on the substrate, so that there is no substrate effect occurred. In addition, not as the cavity construction that there is an etching through-hole or an area occupied by the wafer for back-side etching is preset on the layout of the device, so that the area of the product can be reduced. However, in order to restrict the acoustic wave within the piezoelectric layer 48 effectively, a stacked construction, which is alternately grown with several high-acoustic-impedance layers and several low-acoustic-impedance layers, each has a thickness of quarter wavelength, is used as a reflection surface. As the losses of the acoustic wave between the stacked layers of the construction are rather large, and as the interfacial effect between the multi-layer films of the stacked construction is influential, the quality of the devices may be lowered greatly. Therefore, the structure with multi-layer films is disadvantageous to the quality of the devices.

### SUMMARY OF THE INVENTION

Accordingly, the present invention is objected to improve the above-mentioned defects of conventional art.

Therefore, it is an object of the present invention to provide a method for manufacturing a film bulk acoustic wave filter that no need for etching the backside substrate and the front-side sacrificial layer, and the processing complexity is lowered.

Another object of the present invention is to provide a method for manufacturing a film bulk acoustic wave filter, wherein the size of die is reduced, so that it is much fitter for the requirement of the modern information apparatuses.

A further another object of the present invention is to provide a method for manufacturing a film bulk acoustic wave filter, which is enabled to improve the properties of the filter device and to improve the manufacturing and packaging yield of the device.

To accomplish the above-mentioned objects, in the method for manufacturing a film bulk acoustic wave filter according to the present invention, a reflection layer below the bulk acoustic wave device is formed by using a single-layer high-acoustic-impedance reflection film. It is applied as an interface for reflecting the acoustic wave, and the cavity with low acoustic impedance is not applied.

To accomplish the above-mentioned objects, in the method for manufacturing a film bulk acoustic wave filter according to the present invention, a reflection layer below the bulk acoustic wave device is formed by using a single-layer high-acoustic-impedance reflection film, so that the cavity is no need to be etched, the area of the etching through hole for the front-side etching and the area of the large grains for backside etching can be omitted, and the die size is reduced.

To accomplish the above-mentioned objects, in the method for manufacturing a film bulk acoustic wave filter according to the present invention, a diamond film or a diamond-like film, both with high acoustic impedance and well hardness, or a BCB film with low acoustic impedance, is applied for the single-layer high-acoustic-impedance reflection layer. Thereby, there is no need for etching the cavity and since the construction becomes more steady, the device damage generated by dicing and packaging is prevented.

To accomplish the above-mentioned objects, in the method for manufacturing a film bulk acoustic wave filter according to the present invention, a diamond film or diamond-like film, both with high acoustic impedance and well conductivity, is applied for the single-layer high-acoustic-impedance reflection layer. Thereby, it is advantageous for heat removal during high-power proceeding, and it is also advantageous to be integrated with other semiconductor processes.

The present invention will be better understood and its numerous objects and advantages will become apparent to those skilled in the art by referencing to the accompanying drawings.

### BRIEF DESCRIPTION OF THE DRAWINGS

FIG. 1 is a cross-sectional view of the film bulk acoustic wave device that is backside-etched according to the prior art.

FIG. 2 is a cross-sectional view of the bulk acoustic wave device wherein the substrate is front-etched according to the prior art.

FIG. 3 is a cross-sectional view of the bulk acoustic wave device that is front-side etched by using a sacrificial layer according to the prior art.

FIG. 4 is a cross-sectional view of the reflection layer of the film bulk acoustic wave device formed by multi-layer high-low-acoustic-impedance layers according to the prior art.

FIGS. 5A through 5E are cross-sectional views of the reflection layer of the film bulk acoustic wave device formed by single-layer high-acoustic-impedance reflection layer according to the first embodiment of the present invention.

FIGS. 6A through 6E are cross-sectional views of the reflection layer of the film bulk acoustic wave device formed by single-layer high-acoustic-impedance reflection layer according to the second embodiment of the present invention.

FIGS. 7A through 7E are cross-sectional views of the reflection layer of the film bulk acoustic wave device formed by single-layer high-acoustic-impedance reflection layer, and it is integrated with other semiconductor process according to the third embodiment of the present invention.

FIGS. 8A through 8H are cross-sectional views of the reflection layer of the film bulk acoustic wave device formed by single-layer high-acoustic-impedance reflection layer, and it is integrated with other integration film passive devices processes according to the fourth embodiment of the present invention.

### DETAILED DESCRIPTION OF THE PREFERRED EMBODIMENT

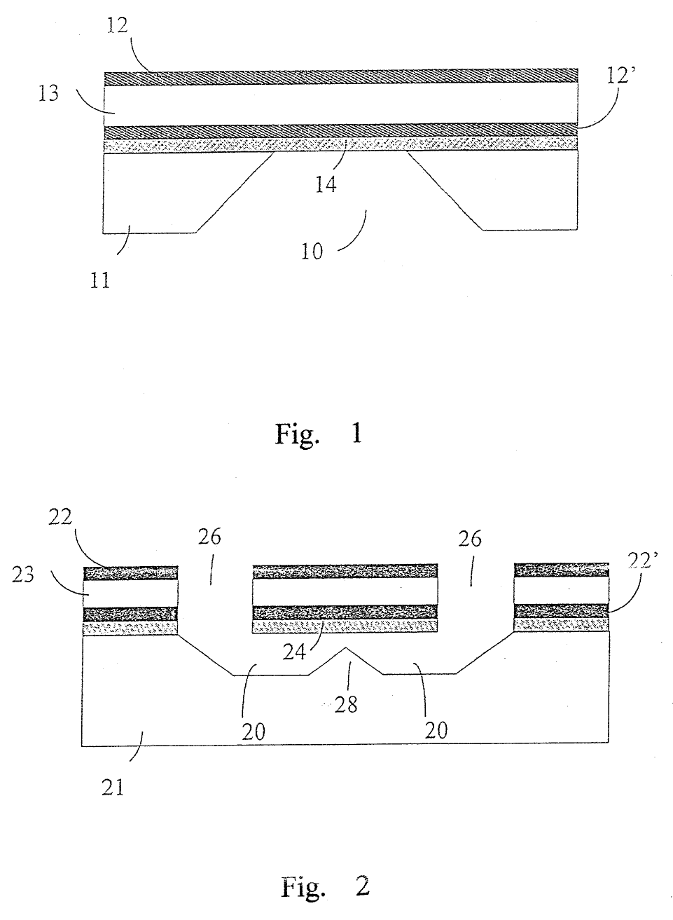

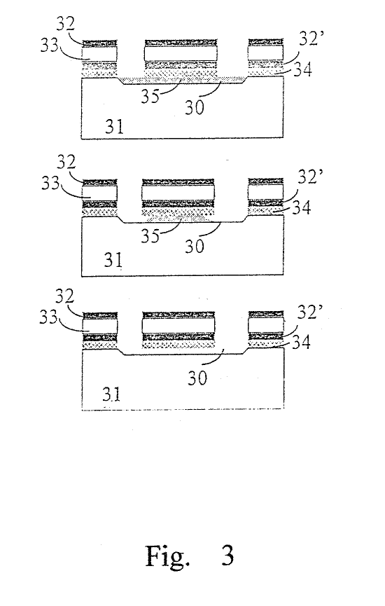

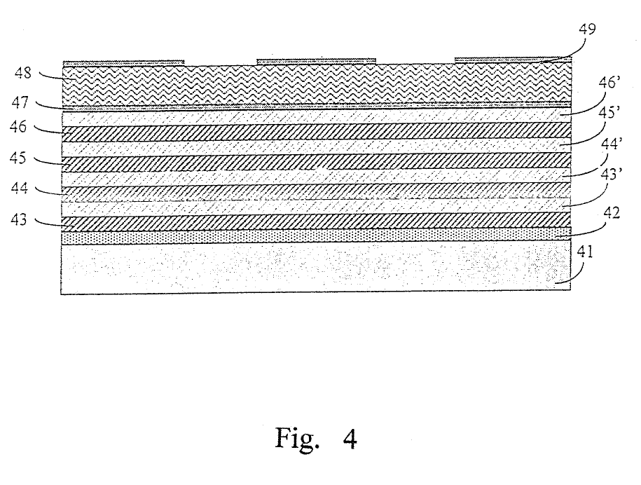

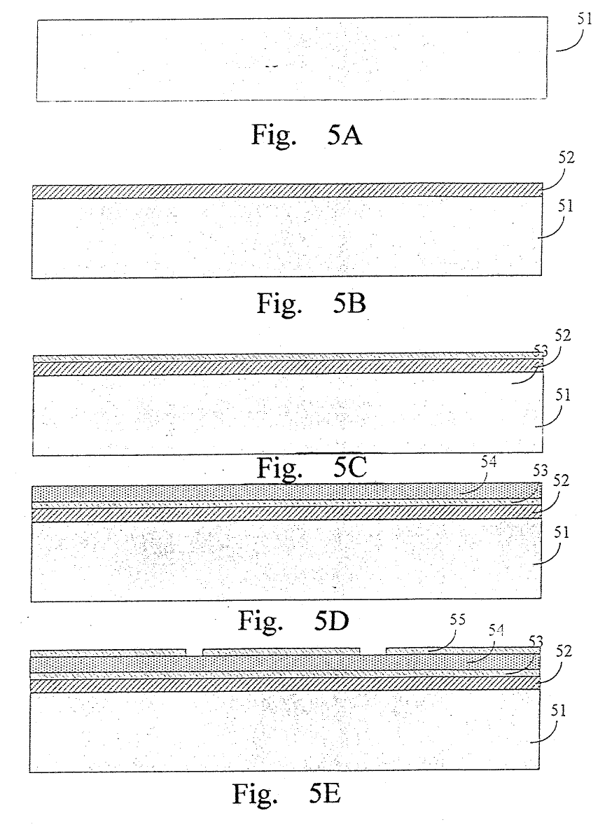

FIGS. 1 through 4 are the cross-sectional views of the bulk acoustic filter using rear etching and front etching according to the conventional technology and have been described already, so they are not repeated.

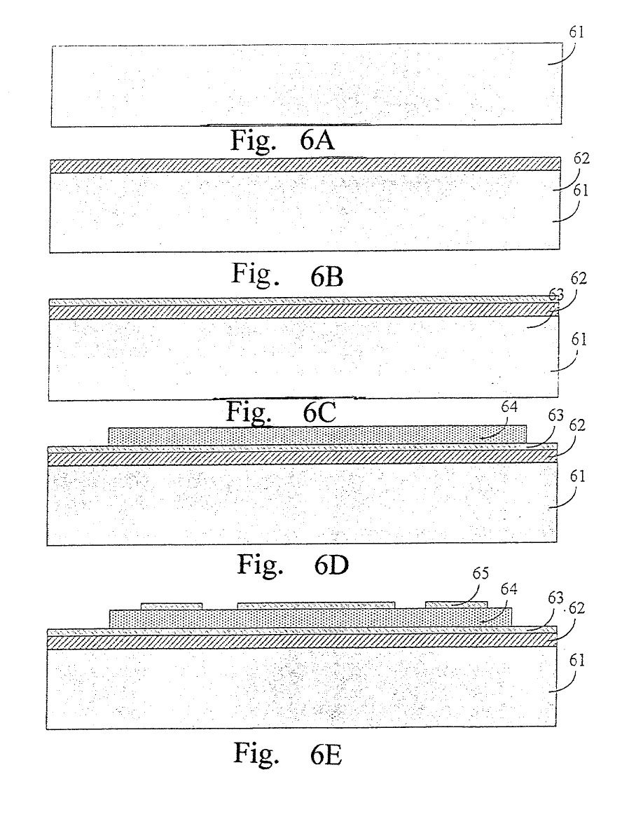

FIGS. 5A through 5E are cross-sectional views of the reflection layer of the film bulk acoustic wave device formed by single-layer high-acoustic-impedance reflection layer according to the first embodiment of the present invention. There is no need for etching the sacrificial layer or the substrate for the whole process. Since the film surface is maintained smooth, the electrode and the piezoelectric material layer are quality assured. Thus a steady device is achieved, and the yield is improved. As shown in FIGS. 5A and 5B, the bulk acoustic wave filter can be formed on a substrate 51. Firstly, a single-layer high-acoustic-impedance reflection layer 52 is deposited onto the substrate 51. Then, the lower electrode layer 53, the piezoelectric layer 54, and the upper electrode metal pattern layer 55 are formed sequentially on this construction, as shown in FIGS. 5C through 5E. Generally, since the path of the acoustic wave is also composed by the supporting layer, the quality of the device must be lowered. In this embodiment, as the bulk acoustic wave device with vacant construction is not applied, a supporting layer for supporting the film should be grown, so that the quality of the device is improved greatly. In addition, this embodiment has the advantages of the multi-layer SBAR (stack bulk acoustic resonator) devices, that is, since the acoustic wave on the substrate is spreaded completely inside the piezoelectric layer, there is no need to consider with the properties of the substrate, and there is no substrate effect completely. Meanwhile, not as the bulk acoustic wave device with cavity construction, it is no need to consider with complicated formula of the etchant, such as the etching selection rate of the substrate and the acoustic wave materials, etc., and the complication of construction thereof. The high-acoustic-impedance reflection layer 52 of this embodiment can be a low-acoustic-impedance film such as BCB film, polymide film, or a high-acoustic-impedance hard film such as a diamond-like film or a diamond film, or other kinds of hard film and extra-hard film such as TiCN, TiN, TiAlN, CrN, ZrN. The hard film has advantages such as high hardness, extremely high acoustic impedance, low rubbing coefficient, excellent electric insulation, and shows extremely high efficiencies in thermal conductivity, acid resistance and alkaline resistance, chemical inactivity, optical permeability, bio-capacity, smoothness and abrasion resistance. Because of these superior properties, it is more extensively applied to mechanical, electrical, semiconductor industries. A plasma with a relative low temperature can be applied to assist the deposition such as PECVD (plasma enhanced chemical vapor deposition), ion beam evaporating, electric-arc ion depositing, non-equilibrium magnetron spilling evaporating, etc. Wherein, the diamond-like film has an excellent smoothness (Ra<10 nm). It is extensively applied to the industry as protection layers for optical lenses, masks of missiles, windows of aircraft, CD-ROMs or disks for computers, the integrated circuits, molds, dicing tools, high density capacitance, and bio-medical materials. The detailed specifications of the diamond-like film are as follows:

(1) high hardness (3,000 to 6,000 kgmm-2)

(2) strong-acid or strong-alkali resistance

(3) the surface is certain smooth (Ra<10 nm)

(4) extremely low rubbing coefficient

(5) extremely low surface energy, excellent mold-stripping properties

(6) good electric insulation (108 to 1,013 ohm-cm)

(7) high electric conductive properties (4 to 10 W/m-K)

(8) excellent bio-capacity

(9) good abrasion resistance

(10) can be grown at room temperature (25° C.)

(11) suitable for all kinds of substrate (including plastic or metal, conductor or insulator)

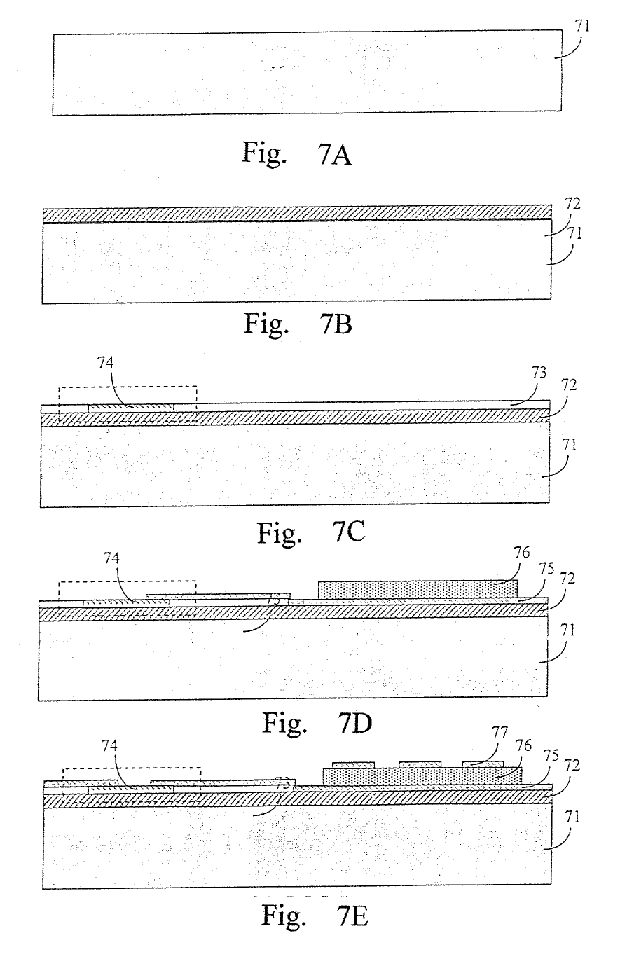

FIGS. 6A through 6E are cross-sectional views of the reflection layer of the film bulk acoustic wave device formed by single-layer high-acoustic-impedance reflection layer according to the second embodiment of the present invention. In order to keep a relatively smooth surface of the film and a good quality of electrode and piezoelectric material thereafter, it is no need for etching the sacrificial layer and the substrate at whole process, thus a steady device is obtained and the yield is improved. As shown in FIGS. 6A and 6B, the bulk acoustic filter device can be formed on a substrate 61. Firstly, a single-layer high-acoustic-impedance reflection layer 62 is deposited onto the substrate 61. Then the lower electrode metal layer 63 and the piezoelectric layer 64 are formed sequentially on this construction. Thereafter, as shown in FIGS. 6C and 6D, the piezoelectric layer 64 is petterned-defined by the mask, and the lower electrode metal layer is exposed for electrically connection. Afterwards, as shown in FIG. 6E, the upper electrode metal pattern 65 is formed on the piezoelectric layer 64.

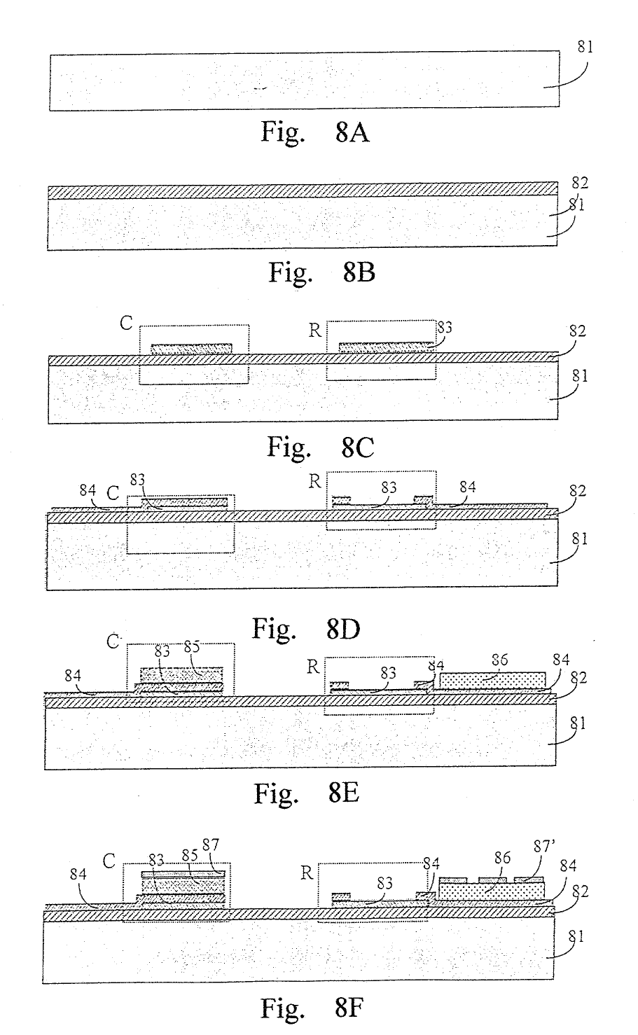

FIGS. 7A through 7E are cross-sectional views showing the reflection layer of the film bulk acoustic wave device formed by single-layer high-acoustic-impedance reflection layer, and it is integrated with other semiconductor process according to the third embodiment of the present invention. As shown in FIGS. 7A and 7B, the bulk acoustic filter device can be formed on a substrate 71. Firstly, a single-layer high-acoustic-impedance reflection layer 72 is deposited onto the substrate 71. Afterwards, as shown in FIG. 7C, a polycrystalline silicon layer 73 is formed on this construction, and a semiconductor device structure 74 is formed on a selected region. And, as shown in FIGS. 7D and 7E, a lower electrode metal layer 75, piezoelectical patterns 76, and upper electrode metal layer 77 of the bulk acoustic wave device are sequentially grown, wherein the upper electrode metal layer 77 is used for electrically connecting the bulk acoustic wave device and the semiconductor device.

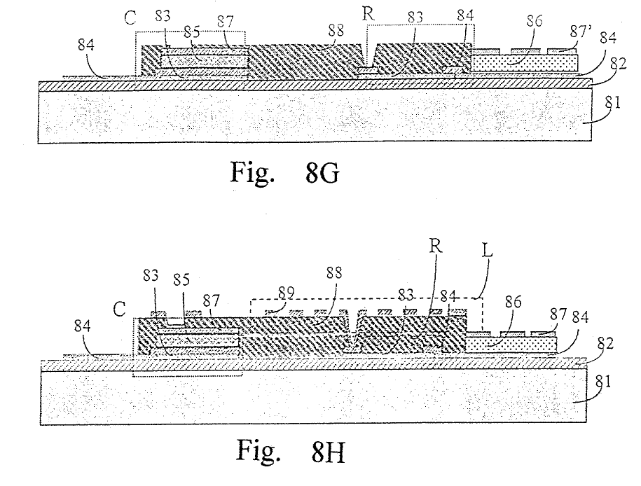

FIGS. 8A through 8H are cross-sectional views showing the reflection layer of the film bulk acoustic wave device formed by single-layer high-acoustic-impedance reflection layer, and it is integrated with other integration film passive devices processes according to the fourth embodiment of the present invention. As shown in FIGS. 8A and 8B, the bulk acoustic wave device and the integrated passive device can be formed on a substrate 81. Firstly, a single-layer high-acoustic-impedance reflection layer 82 is deposited onto the substrate 81. Afterwards, as shown in FIGS. 8C and 8D, lower resistance materials 83 and a first metal layer pattern 84 are formed sequentially on this construction. The first metal layer pattern 84 can also be used for electrically connecting the lower electrode of the capacitor and the resistance. Thereafter, as shown in FIG. 8E, a dielectric layer 85 and a piezoelectric layer 86 of the bulk acoustic device are formed on the capacitor region. And, the piezoelectric layer 86 is petterned-defined by the mask, and the lower electrode metal layer 82 is exposed for electrically connection. Afterwards, as shown in FIG. 8F, second metal layers 87 and 87′ are formed respectively on the dielectric layer 85 of the capacitor and the piezoelectric layer 86 of the resistance. FIGS. 8G and 8H are cross-sectional views showing the following process of forming an upper inductor. As shown in the figures, a dielectric layer 88 for isolation is formed firstly. Then it is defined by patterning on the upper surface mask in order to form a through hole window for bonding wires. And then, a third metal layer 89 is deposited for forming an inductor pattern L.

Here, the dielectric layer 88 for isolation can be a material with low dielectric constant chosen from the following group: SiO₂, SOG (spin on glass), PBSG, PSG, BCB. Moreover, the three metal layers composing the upper inductor can be accomplished by applying a thick film metal process such as deposition process in order to improve the inductor efficiency.

Although the present invention has been described using specified embodiment, the examples are meant to be illustrative and not restrictive. It is clear that many other variations would be possible without departing from the basic approach, demonstrated in the present invention.

What is claimed is:

1. A method for manufacturing a film bulk acoustic wave filter, including the following steps:
providing a substrate;
depositing a single-layer high-acoustic-impedance reflection layer on the substrate; and
forming a lower electrode metal layer, a piezoelectric layer, and an upper electrode metal pattern on the resulting construction.

2. The method for manufacturing a film bulk acoustic wave filter as claimed in claim 1, wherein the single-layer high-acoustic-impedance reflection layer can be a hard carbonic film such as a diamond-like film or a diamond film, etc.

3. The method for manufacturing a film bulk acoustic wave filter as claimed in claim 1, wherein the single-layer high-acoustic-impedance reflection is layer can be a hard carbonic film such as the extra-hard film of TiCN, TiN, TiAlN, CrN, ZrN etc.

4. The method for manufacturing a film bulk acoustic wave filter as claimed in claim 1, wherein the single-layer high-acoustic-impedance reflection layer can be a low-acoustic-impedance film of BCB or polyimide etc.

5. A manufacturing method of a film bulk acoustic wave filter, including the following steps:
providing a substrate;
depositing a single-layer high-acoustic-impedance reflection layer on the substrate;
forming a lower electrode metal layer and a piezoelectric layer on the resulting construction; and
defining the piezoelectric layer by patterning a mask to expose the lower electrode metal layer for electrically connection; and
forming an upper electrode metal pattern on the piezoelectric layer.

6. The method for manufacturing a film bulk acoustic wave filter as claimed in claim 5, the single-layer high-acoustic-impedance reflection layer can be a hard carbonic film such as a diamond-like film or a diamond film etc.

7. The method for manufacturing a film bulk acoustic wave filter as claimed in claim 5, wherein the single-layer high-acoustic-impedance reflection layer can be a hard carbonic film such as the extra-hard film of TiCN, TiN, TiAlN, CrN, ZrN etc.

8. The method for manufacturing a film bulk acoustic wave filter as claimed in claim 5, wherein wherein the single-layer high-acoustic-impedance reflection layer can be a low-acoustic-impedance film of BCB or polyimide, etc.

9. A manufacturing method of a film bulk acoustic wave filter, including the following steps:
providing a substrate;
depositing a single-layer high-acoustic-impedance reflection layer on the substrate;
forming a poly-crystalline silicon layer sequentially on the resulting construction;
forming a semiconductor device on selected region;
forming a lower electrode metal layer and a piezoelectric layer on the resulting construction;
defining the piezoelectric layer by patterning a mask to expose the lower electrode metal layer for electrically connection; and
forming an upper electrode metal pattern on the piezoelectric layer.

10. The method for manufacturing a film bulk acoustic wave filter as claimed in claim 9, wherein the single-layer high-acoustic-impedance reflection layer can be a hard carbonic film such as a diamond-like film or a diamond film etc.

11. The method for manufacturing a film bulk acoustic wave filter as claimed in claim 9, wherein the single-layer high-acoustic-impedance reflection layer can be a hard carbonic film such as the extra-hard film of TiCN, TiN, TiAlN, CrN, ZrN etc.

12. The method for manufacturing a film bulk acoustic wave filter as claimed in claim 9, wherein the single-layer high-acoustic-impedance reflection layer can be a low-acoustic-impedance film of BCB or polyimide etc.

13. A manufacturing method of a film bulk acoustic wave filter, including the following steps:
providing a substrate;
depositing a single-layer high-acoustic-impedance reflection layer on the substrate;
forming a lower resistant material on the resulting construction; forming a first metal pattern;
forming a dielectric layer;
forming a piezoelectric layer;
deforming the piezoelectric layer by patterning a mask to expose the lower electrode metal layer for electrically connection;
forming second metal patterns on the piezoelectric layer and the dielectric layer;
forming a dielectric layer for isolating; and
patterning a mask, forming a through hole window for bonding wire, and depositing a third metal layer to form a inductor pattern.

14. The method for manufacturing a film bulk acoustic wave filter as claimed in claim 13, wherein the single-layer high-acoustic-impedance reflection layer can be a hard carbonic film such as a diamond-like film or a diamond film etc.

15. The method for manufacturing a film bulk acoustic wave filter as claimed in claim 13, wherein the single-layer high-acoustic-impedance reflection layer can be a hard carbonic film such as the extra-hard film of TiCN, TiN, TiAlN, CrN, ZrN etc.

16. The method for manufacturing a film bulk acoustic wave filter as claimed in claim 13, wherein the single-layer high-acoustic-impedance reflection layer can be a low-acoustic-impedance film of BCB or polyimide etc.

17. The method for manufacturing a film bulk acoustic wave filter as claimed in claim 13, wherein the first metal pattern is applied for electrically connecting the lower electrode of the capacitor and the resistance.

18. The method for manufacturing a film bulk acoustic wave filter as claimed in claim 13, wherein the second metal layer is applied as the upper electrode metal pattern of the capacitor and the upper electrode metal pattern of the piezoelectric layer.

19. The method for manufacturing a film bulk acoustic wave filter as claimed in claim 13, wherein thee third metal layer is applied as the pattern for composing an inductor.

20. The method for manufacturing a film bulk acoustic wave filter as claimed in claim 13, wherein the piezoelectric layer for isolation is a material with low dielectric constant chosen from the grope of SOG, PBSG, PSG, BCB.

21. The method for manufacturing a film bulk acoustic wave filter as claimed in claim 13, wherein the third metal layer for forming the upper inductor can also be applied by thick film metal process such as depositing process.
